(19) United States
(12) Patent Application Publication
(10) Pub. No.: US 2025/0089480 A1
(43) Pub. Date: Mar. 13, 2025

(54) ELECTRONIC DEVICE

(71) Applicant: InnoLux Corporation, Miao-Li County (TW)

(72) Inventors: Hsiao-Lang LIN, Miao-Li County (TW); Tsung-Han TSAI, Miao-Li County (TW)

(21) Appl. No.: 18/799,538

(22) Filed: Aug. 9, 2024

(30) Foreign Application Priority Data
Sep. 12, 2023 (CN) 202311170747.7

(51) Int. Cl. H10K 59/126; H01L 33/50; H01L 33/62; H10K 59/131; H10K 59/38

(52) U.S. Cl. CPC H10K 59/126; H10H 20/851; H10H 20/857; H10K 59/131; H10K 59/38

(57) ABSTRACT

An electronic device is provided. The electronic device includes a substrate, a signal line, a first electronic unit, a conductive structure and a light blocking layer. The signal line is disposed on the substrate. The first electronic unit is disposed on the substrate and includes a first electrode. The conductive structure is disposed on the substrate and includes a first conductive pattern, an insulating layer disposed on the first conductive pattern, and a second conductive pattern disposed on the insulating layer. The second conductive pattern is electrically connected to the first conductive pattern through a first opening of the insulating layer. The first electrode is electrically connected to the signal line through the conductive structure. The light blocking layer is overlapped with the conductive structure.

### CROSS REFERENCE TO RELATED APPLICATIONS

This application claims the benefit of China Application No. 202311170747.7, filed Sep. 12, 2023, the entirety of which is incorporated by reference herein.

### BACKGROUND

### Technical Field

The present disclosure is related to an electronic device, and in particular it is related to an electronic device that can improve the visibility of electrical connection structures.

### Description of the Related Art

Electronic devices such as tablet computers, notebook computers, smartphones, monitors, and televisions have become indispensable necessities in modern society. With the ongoing development of these portable electronic devices, consumers have high expectations regarding the quality, functionality or price of these products.

As electronic devices become larger in size, some electronic components need to be electrically connected through additional auxiliary structures to improve problems such as excessive impedance. However, these electrical connection structures may cause other problems that can affect the performance of the electronic device. For example, the obvious visibility of an electrical connection structure may affect the display quality of the electronic device or cause signal interference.

As described above, existing electronic devices still do not meet users' needs in all respects. Further improving the performance of the electrical connection structure of electronic devices is still one of the current research topics in the industry.

### SUMMARY

In accordance with some embodiments of the present disclosure, an electronic device is provided. The electronic device includes a substrate, a signal line, a first electronic unit, a conductive structure, and a light blocking layer. The signal line is disposed on the substrate. The first electronic unit is disposed on the substrate and includes a first electrode. The conductive structure is disposed on the substrate and includes a first conductive pattern, an insulating layer disposed on the first conductive pattern, and a second conductive pattern disposed on the insulating layer. The second conductive pattern is electrically connected to the first conductive pattern through a first opening of the insulating layer. The first electrode is electrically connected to the signal line through the conductive structure. The light blocking layer is overlapped with the conductive structure.

A detailed description is given in the following embodiments with reference to the accompanying drawings.

### BRIEF DESCRIPTION OF THE DRAWINGS

The disclosure may be more fully understood by reading the subsequent detailed description and examples with references made to the accompanying drawings, wherein:

FIG. 1 is a cross-sectional diagram of an electronic device in accordance with some embodiments of the present disclosure;

FIG. 2 is a top-view diagram of an electronic device in accordance with some embodiments of the present disclosure;

FIG. 3 is a cross-sectional diagram of the electronic device taken along the section line A-A′ in FIG. 2 in accordance with some embodiments of the present disclosure;

FIG. 4 is an equivalent circuit diagram of an electronic device in accordance with some embodiments of the present disclosure;

FIG. 5 is a cross-sectional diagram of an electronic device in accordance with some embodiments of the present disclosure;

FIG. 6 is a top-view diagram of some components of an electronic device in accordance with some embodiments of the present disclosure;

FIG. 7 is a cross-sectional diagram of the electronic device taken along the section line B-B′ in FIG. 6 in accordance with some embodiments of the present disclosure;

FIG. 8A to FIG. 8G are top-view diagrams of some components of an electronic device in accordance with some embodiments of the present disclosure;

FIG. 9 is a top-view diagram of an electronic device in accordance with some embodiments of the present disclosure.

### DETAILED DESCRIPTION

The electronic device according to the present disclosure are described in detail in the following description. It should be understood that in the following detailed description, for purposes of explanation, numerous specific details and embodiments are set forth in order to provide a thorough understanding of the present disclosure. The elements and configurations described in the following detailed description are set forth in order to clearly describe the present disclosure. These embodiments are used merely for the purpose of illustration, and the present disclosure is not limited thereto. In addition, different embodiments may use like and/or corresponding numerals to denote like and/or corresponding elements in order to clearly describe the present disclosure. However, the use of like and/or corresponding numerals of different embodiments does not suggest any correlation between different embodiments.

It should be understood that relative expressions may be used in the embodiments. For example, “lower”, “bottom”, “higher” or “top” are used to describe the position of one element relative to another. It should be appreciated that if a device is flipped upside down, an element that is “lower” will become an element that is “higher”. The present disclosure can be understood by referring to the following detailed description in connection with the accompanying drawings. The drawings are also regarded as part of the description of the present disclosure. It should be understood that the drawings of the present disclosure may be not drawn to scale. In fact, the size of the elements may be arbitrarily enlarged or reduced to clearly represent the features of the present disclosure.

Furthermore, the expression “a first material layer is disposed on or over a second material layer” may indicate that the first material layer is in direct contact with the second material layer, or it may indicate that the first material layer is in indirect contact with the second material layer. In the situation where the first material layer is in indirect contact with the second material layer, there may be one or more intermediate layers between the first material layer and the second material layer. However, the expression “the first material layer is directly disposed on or over the second material layer” means that the first material layer is in direct contact with the second material layer, and there is no intermediate element or layer between the first material layer and the second material layer.

Moreover, it should be understood that the ordinal numbers used in the specification and claims, such as the terms “first”, “second”, etc., are used to modify an element, which itself does not mean and represent that the element (or elements) has any previous ordinal number, and does not mean the order of a certain element and another element, or the order in the manufacturing method. The use of these ordinal numbers is to make an element with a certain name can be clearly distinguished from another element with the same name. Claims and the specification may not use the same terms. For example, the first element in the specification may refer to the second element in the claims.

In accordance with the embodiments of the present disclosure, regarding the terms such as “connected to”, “interconnected with”, etc. referring to bonding and connection, unless specifically defined, these terms mean that two structures are in direct contact or two structures are not in direct contact, and other structures are provided to be disposed between the two structures. The terms for bonding and connecting may also include the case where both structures are movable or both structures are fixed. In addition, the term “electrically connected to” or “coupled to” may include any direct or indirect electrical connection means.

In the following descriptions, terms “about”, “substantially” and “approximately” typically mean +/−10% of the stated value, or typically +/−5% of the stated value, or typically +/−3% of the stated value, or typically +/−2% of the stated value, or typically +/−1% of the stated value or typically +/−0.5% of the stated value. The expression “in a range from the first value to the second value” or “between the first value and the second value” means that the range includes the first value, the second value, and other values in between. Moreover, certain errors may exist between any two values or directions used for comparison. If the first value is equal to the second value, it implies that there may be an error of about 10% between the first value and the second value; if the first direction is perpendicular to the second direction, the angle between the first direction and the second direction may be between 80 degrees and 100 degrees; if the first direction is parallel to the second direction, the angle between the first direction and the second direction may be between 0 degrees and 10 degrees.

It should be understood that in the following embodiments, without departing from the spirit of the present disclosure, the features in several different embodiments can be replaced, recombined, and mixed to complete another embodiment. The features between the various embodiments can be mixed and matched arbitrarily as long as they do not violate or conflict the spirit of the present disclosure.

Unless defined otherwise, all technical and scientific terms used herein have the same meaning as commonly understood by one of ordinary skill in the art to which this disclosure belongs. It should be appreciated that, in each case, the term, which is defined in a commonly used dictionary, should be interpreted as having a meaning that conforms to the relative skills of the present disclosure and the background or the context of the present disclosure, and should not be interpreted in an idealized or overly formal manner unless so defined.

As electronic devices become larger in size, some electronic components need to be electrically connected through additional auxiliary structures to improve problems such as excessive impedance. However, these electrical connection structures may cause other problems that affect the performance of the electronic device.

In accordance with some embodiment of the present disclosure, an electronic device is provided, including a conductive structure that electrically connects an electrode of an electronic unit to a signal line. The conductive structure can reduce voltage drop (IR drop) caused by high impedance of the electrode. In addition, since the conductive structure overlaps with the light blocking layer, the obvious visibility of the conductive structure can be improved, thereby improving the problems of declining display quality or signal interference of the electronic device. The overall performance of the electronic device therefore can be enhanced.

In accordance with some embodiments of the present disclosure, the electronic device may include a display device, a tiled device, a touch electronic device, a sensing device, a curved electronic device or a non-rectangular electronic device, but it is not limited thereto. The electronic device may include, for example, liquid crystal, light emitting diode, fluorescence, phosphor, another suitable display medium, or a combination thereof, but it is not limited thereto. The display device may be a non-self-luminous display device or a self-luminous display device. The electronic device may include an electronic unit, and the electronic unit may be a passive component or an active component, such as a capacitor, a resistor, an inductor, a diode, a transistor, etc. The diode may include a light-emitting diode (LED) or a photodiode. The light-emitting diode may include, for example, an organic light-emitting diode (OLED), a mini light-emitting diode (mini LED), a micro-light-emitting diode (micro LED) or a quantum dot light-emitting diode (QLED), but it is not limited thereto. The tiled device may be, for example, a tiled display device, but it is not limited thereto. It should be noted that the electronic device can be any combination of the above, but it is not limited thereto. In addition, the electronic device may be a bendable or flexible electronic device. In addition, the shape of the electronic device may be a rectangular shape, a circular shape, a polygonal shape, a shape with curved edges, or another suitable shape. The electronic device may have a peripheral system such as a driving system, a control system, a light source systems, a shelf system, etc. to support a display device or a tiled device. For convenience of explanation, the following description will take the electronic device as a display device as an example, but the present disclosure is not limited thereto.

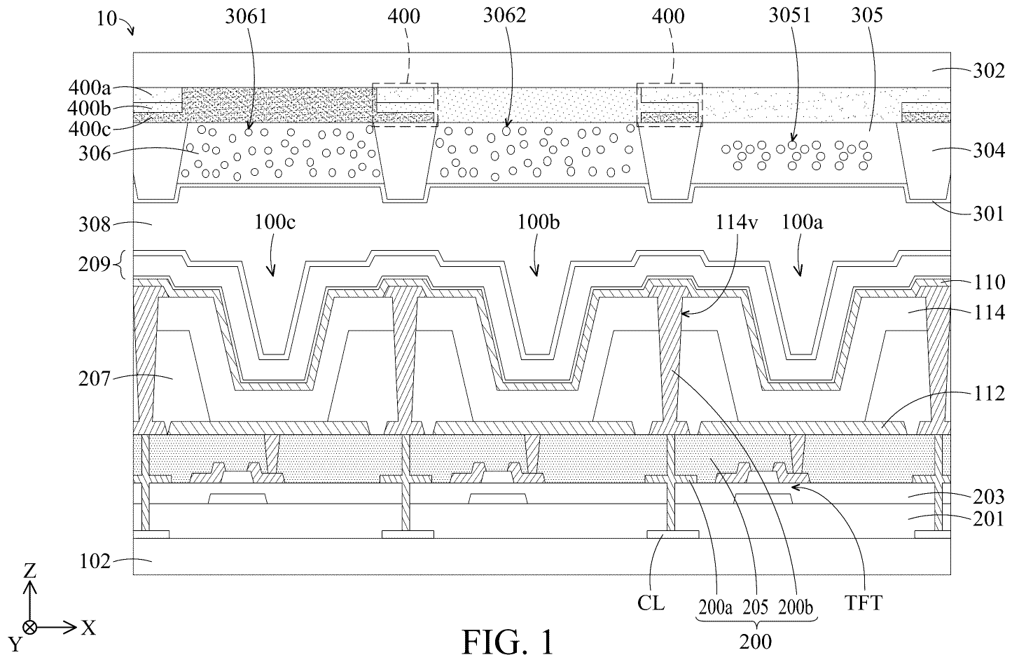

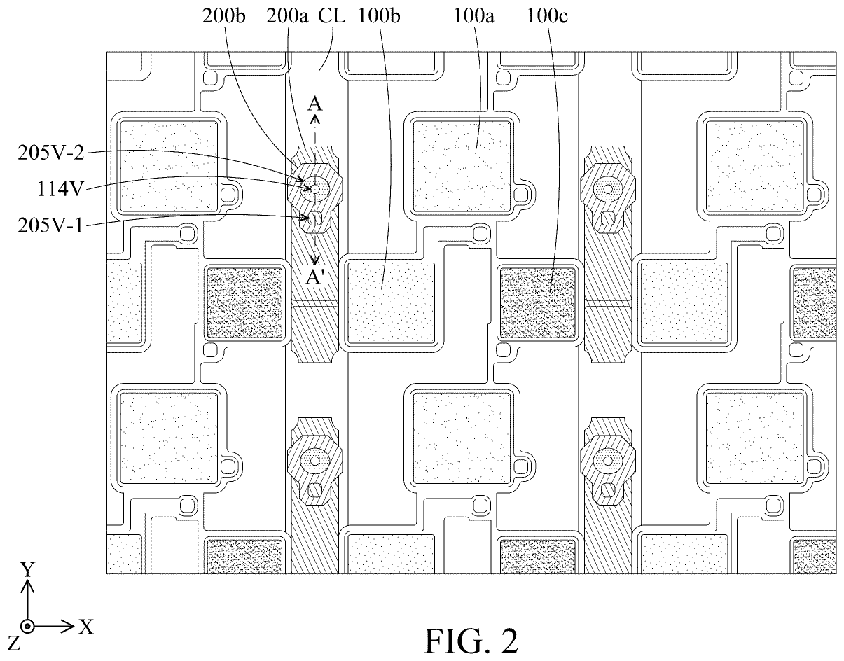

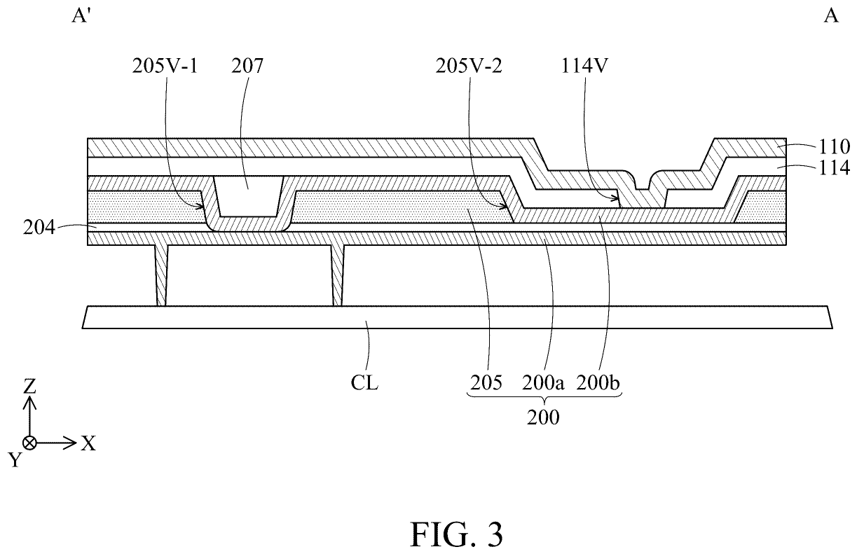

Please refer to FIG. 1, FIG. 2 and FIG. 3. FIG. 1 is a cross-sectional diagram of an electronic device 10 in accordance with some embodiments of the present disclosure. FIG. 2 is a top-view diagram of the electronic device 10 in accordance with some embodiments of the present disclosure. FIG. 3 is a cross-sectional diagram of the electronic device 10 taken along the section line A-A′ in FIG. 2 in accordance with some embodiments of the present disclosure. It should be understood that, for clarity of explanation, some components of the electronic device 10 may be omitted in the drawings, and only some components are schematically shown. In accordance with some embodiments, additional features may be added to the electronic device 10 described below. Specifically, FIG. 2 and FIG. 3 only illustrate some of the components in FIG. 1 to illustrate the connection relationship between the conductive structure 200 and other components (for example, the first electrode 110 and the signal line CL, etc.). In addition, it should be understood that FIG. 1 does not illustrate the detailed structure of the conductive structure 200. For the detailed structure of the conductive structure 200, please refer to t FIG. 2 and t FIG. 3.

As shown in FIG. 1, the electronic device 10 may include a substrate 102, a signal line CL, an electronic unit 100a, a conductive structure 200, and a light blocking layer 400. The signal line CL, the electronic unit 100a, and the conductive structure 200 may be disposed on the substrate 102. The light blocking layer 400 may overlap with the conductive structure 200. Specifically, the light blocking layer 400 may overlap with the conductive structure 200 in the normal direction of the substrate 102 (e.g., the Z direction in the figure).

In accordance with some embodiments, an active driving circuit and/or a passive driving circuit may be fabricated on the substrate 102. For example, as shown in FIG. 1, the electronic device 10 may include a thin-film transistor TFT (e.g., a switching transistor, a driving transistor, a reset transistor, a transistor amplifier, or another suitable thin-film transistor), signal line CL, a dielectric layer 201 and a gate dielectric layer 203 disposed on the substrate 102. The thin-film transistor TFT may include at least one semiconductor layer and a gate electrode layer. The semiconductor layer may include doped regions with appropriate dopants and a channel region located between the two doped regions, and the doped regions may further have parts with different doping concentrations. Furthermore, the semiconductor layer may include amorphous silicon, low-temp polysilicon (LTPS), metal oxide, another suitable material, or a combination thereof, but it is not limited thereto. The metal oxide may include indium gallium zinc oxide (IGZO), indium zinc oxide (IZO), indium gallium oxide (IGO), indium gallium zinc tin oxide (IGZTO), another suitable material, or a combination thereof, but it is not limited thereto. In addition, although the thin-film transistor TFT illustrated in the drawing is a bottom gate thin-film transistor, the thin-film transistor TFT may also be a top gate thin-film transistor, a bottom gate thin-film transistor, or a dual gate (double gate) thin-film transistor according to different embodiments.

In accordance with some embodiments, the signal line CL may be used to receive a common voltage, but it is not limited thereto. In accordance with some embodiments, the electronic device 10 may further include other signal lines disposed on the substrate 102 such as data lines, scan lines, touch signal lines, etc., but it is not limited thereto.

The substrate 102 may include a rigid substrate or a flexible substrate. In accordance with some embodiments, the material of the substrate 102 may include glass, quartz, sapphire, polyimide (PI), polycarbonate (PC), polyethylene terephthalate (PET), polypropylene (PP), polydimethylsiloxane (PDMS), another suitable material, or a combination thereof, but it is not limited thereto.

In accordance with some embodiments, the electronic unit 100a may include a light emitting unit or a sensing unit, but it is not limited thereto. The light-emitting unit may be specifically a light-emitting diode. Specifically, in accordance with some embodiments, the electronic unit 100a may be a light-emitting unit. The electronic unit 100a may include a first electrode 110, a second electrode 112 and an active layer 114. The second electrode 112 may be disposed under the first electrode 110. The active layer 114 may be disposed between the first electrode 110 and the second electrode 112. In addition, the electronic device 10 may have a plurality of electronic units, such as an electronic unit 100a, an electronic unit 100b and an electronic unit 100c shown in the figure. In accordance with some embodiments, the electronic unit 100a, the electronic unit 100b, and the electronic unit 100c may be pixel units. It should be understood that, for the sake of simplicity, most of the descriptions of the electronic unit herein take the electronic unit 100a as an example, but the relevant description of the electronic unit 100a can also be applied to the electronic unit 100b and the electronic unit 100c.

In accordance with some embodiments, the first electrode 110, the second electrode 112 and the active layer 114 may respectively serve as a cathode, an anode and a light-emitting layer of a light-emitting unit, but they are not limited thereto.

In accordance with some embodiments, the material of the first electrode 110 may include a transparent conductive material or a metallic conductive material, but it is not limited thereto. In accordance with some embodiments, the material of the second electrode 112 may include a metallic conductive material, a transparent conductive material, another suitable material, or a combination thereof, but it is not limited thereto. The transparent conductive material may include, for example, transparent conductive oxide (TCO), for example, may include indium tin oxide (ITO), antimony zinc oxide (AZO), tin oxide (SnO), zinc oxide (ZnO), indium zinc oxide (IZO), indium gallium zinc oxide (IGZO), indium tin zinc oxide (ITZO), antimony tin oxide (ATO), another suitable transparent conductive material, or a combination thereof, but it is not limited thereto. The metallic conductive material may include, for example, copper (Cu), aluminum (Al), indium (In), ruthenium (Ru), tin (Sn), gold (Au), platinum (Pt), molybdenum (Mo), zinc (Zn), silver (Ag), titanium (Ti), lead (Pb), nickel (Ni), neodymium (Nd), iridium (Ir), chromium (Cr), magnesium (Mg), palladium (Pd), lithium (Li), calcium (Ca), alloys of the aforementioned metals, another suitable metal material or a combination thereof, but it is not limited thereto. In addition, in accordance with some embodiments, the active layer 114 may include a charge generation layer (not illustrated), a hole injection layer (not illustrated), an electron injection layer (not illustrated), a hole transport layer (not illustrated), an electron transport layer (not illustrated), an organic light-emitting layer (not illustrated) disposed between the hole transport layer and the electron transport layer, and additive materials (not illustrated) that improve electron hole transport, but it is not limited thereto.

It should be noted that since the first electrode 110 needs to be translucent, it needs to maintain a thin thickness. This may cause the impedance of the first electrode 110 to increase, resulting in uneven emission brightness in different electronic units 100a, 100b, and 100c. In accordance with the embodiments of the present disclosure, the first electrode 110 can be electrically connected to the signal line CL through the conductive structure 200, thereby improving the voltage drop (IR drop) problem caused by the increase in impedance.

In detail, the conductive structure 200 may include a first conductive pattern 200a, an insulating layer 205 disposed on the first conductive pattern 200a, and a second conductive pattern 200b disposed on the insulating layer 205. In accordance with some embodiments, the first conductive pattern 200a may pass through the dielectric layer 201 and the gate dielectric layer 203 to be electrically connected to the signal line CL. Furthermore, referring to FIG. 2 and FIG. 3, the second conductive pattern 200b may be electrically connected to the first conductive pattern 200a through a first opening 205V-1 of the insulating layer 205. In addition, the first electrode 110 of the electronic unit 100a may be electrically connected to the signal line CL through the conductive structure 200. Specifically, the first electrode 110 may be electrically connected to the second conductive pattern 200b of the conductive structure 200 through an opening 114V in the active layer 114. Furthermore, in accordance with some embodiments, the second conductive pattern 200b and the second electrode 112 of the electronic unit 100a may be in the same layer. For example, the second conductive pattern 200b and the second electrode 112 belong to the same layer of the electronic device 10 and are formed together during the manufacturing process.

In addition, in accordance with some embodiments, the insulating layer 205 may further include a second opening 205V-2 overlapped with the second conductive pattern 200b. Specifically, the second opening 205V-2 may overlap with the second conductive pattern 200b in the normal direction of the substrate 102 (e.g., the Z direction in the figure). As shown in FIG. 2 and FIG. 3, in the top view of the electronic device 10, the opening 114V of the active layer 114 may be located in the second opening 205V-2. In other words, the opening 114V of the active layer 114 may overlap with the second opening 205V-2 in the normal direction of the substrate 102. In accordance with some embodiments, the size of the first opening 205V-1 of the insulating layer 205 may be smaller than the size of the second opening 205V-2. In the top view of the electronic device 10, the second conductive pattern 200b may have a gourd-like shape or a circle-like shape, but it is not limited thereto.

In accordance with some embodiments, the materials of the first conductive pattern 200a and the second conductive pattern 200b may include a metallic conductive material, another suitable material, or a combination thereof, but it is not limited thereto. The metallic conductive material may include, for example, copper (Cu), silver (Ag), gold (Au), tin (Sn), aluminum (Al), molybdenum (Mo), tungsten (W), chromium (Cr), nickel (Ni), platinum (Pt), titanium (Ti), palladium (Pd), iridium (Ir), rhodium (Rh), alloys of the aforementioned metals, another suitable metallic conductive material, or a combination thereof, but it is not limited thereto. In accordance with some embodiments, the insulating layer 205 may include an inorganic material, an organic material, or a combination thereof, but it is not limited thereto. In accordance with some embodiments, the inorganic material may include silicon nitride, silicon oxide, silicon oxynitride, aluminum oxide, another suitable material, or a combination thereof, but it is not limited thereto. In accordance with some embodiments, the organic material may include, for example, perfluoroalkoxy alkane (PFA), polytetrafluoroethylene (PTFE), perfluorinated ethylene propylene (FEP), poly ethylene, another suitable material or a combination thereof, but it is not limited thereto.

Moreover, as shown in FIG. 1 and FIG. 3, in accordance with some embodiments, the electronic device 10 may further include an insulating layer 204 and an insulating layer 207. The insulating layer 204 may be disposed between the first conductive pattern 200a and the second conductive pattern 200b, and may be disposed between the first conductive pattern 200a and the insulating layer 205. Furthermore, in accordance with some embodiments, the insulating layer 207 may serve as a pixel definition layer (PDL), and the insulating layer 207 may be disposed between the electronic unit 100a, the electronic unit 10b and the electronic unit 100c to define the position of the electronic units. The insulating layer 207 may be disposed on the insulating layer 205, and the insulating layer 207 may partially overlap with the second electrode 112 in the normal direction of the substrate 102 (e.g., the Z direction in the figure). In accordance with some embodiments, the insulating layer 207 may be disposed in the first opening 205V-1 of the insulating layer 205. In accordance with some embodiments, the second conductive pattern 200b may also be electrically connected to the first conductive pattern 200a through the first opening 205V-1 of the insulating layer 205, and the second conductive pattern 200b may also be electrically connected to the first conductive pattern 200a through a common opening (not labeled) of the insulating layer 204 and the insulating layer 205, but it is not limited thereto.

In accordance with some embodiments, the materials of the insulating layer 204 and the insulating layer 207 may be the same as or similar to the material of the aforementioned insulating layer 205, and will not be repeated here. In accordance with some embodiments, the material of the insulating layer 204 may be an inorganic material, which may include silicon nitride, silicon oxide, silicon oxynitride, aluminum oxide, another suitable material, or a combination thereof, but it is not limited thereto.

Furthermore, as shown in FIG. 1, in accordance with some embodiments, the light blocking layer 400 may include a first color filter layer 400a, a second color filter layer 400b, and a third color filter layer 400c stacked on each other, and the first color filter layer 400a, the second color filter layer 400b and the third color filter layer 400c may have different colors. The color filter layer can filter or adjust the optical properties of light passing through it, for example, allowing light in a specific wavelength range to pass. In accordance with some embodiments, the first color filter layer 400a, the second color filter layer 400b and the third color filter layer 400c may be a blue color filter layer, a green color filter layer and a red color filter layer, respectively, but they are not limited thereto. In accordance with some embodiments, the first color filter layer 400a, the second color filter layer 400b and the third color filter layer 400c may be respectively disposed corresponding to the electronic unit 100a, the electronic unit 100b and the electronic unit 100c.

It should be noted that the first color filter layer 400a, the second color filter layer 400b and the third color filter layer 400c that overlap with each other have a very low transmittance for visible light. As mentioned above, the light blocking layer 400 including the first color filter layer 400a, the second color filter layer 400b and the third color filter layer 400c stacked on each other may overlap with the conductive structure 200 in the normal direction of the substrate, so that the light blocking layer 400 can be used to shield the conductive structure 200. The visibility of the conductive structure 200 can be reduced, thereby improving the display quality of the electronic device 10 and enhancing the overall performance of the electronic device 10. Furthermore, in the embodiments where the electronic device 10 is used as a sensing device, the conductive structure 200 can also block stray light to reduce problems such as signal interference.

Please refer to FIG. 1 again. In accordance with some embodiments, the electronic device 10 may further include an encapsulation layer 209. The encapsulation layer 209 may be disposed on the first electrode 110 to reduce the impact of water vapor or oxygen on the first electrode 110 and the underlying structure. In accordance with some embodiments, the encapsulation layer 209 may have a multi-layer structure, for example, a structure having an inorganic layer, an organic layer, and an inorganic layer arranged in sequence (I-O-I).

In accordance with some embodiments, the material of the inorganic layer of the encapsulation layer 209 may include silicon nitride, silicon oxide, silicon oxynitride, aluminum oxide, another suitable material, or a combination thereof, but it is not limited thereto. In accordance with some embodiments, the organic material of the encapsulation layer 209 may include epoxy resin, silicone resin, acrylic resin (such as polymethylmethacrylate (PMMA)), polyimide, perfluoroalkoxy alkane (PFA), another suitable material or a combination thereof, but it is not limited thereto.

In addition, the electronic device 10 may include a substrate 302 disposed opposite to the substrate 102, and the substrate 302 may serve as a color filter substrate. The substrate 302 may include a rigid substrate or a flexible substrate. The material of the substrate 302 may be the same as or similar to the material of the substrate 102, and will not be repeated here.

The first color filter layer 400a, the second color filter layer 400b and the third color filter layer 400c may be disposed on the substrate 302. Furthermore, the light blocking layer 400 formed by stacking the first color filter layer 400a, the second color filter layer 400b, and the third color filter layer 400c may also be disposed on the substrate 302.

In accordance with some embodiments, the material of the color filter layer may include color photoresist. The material of the color photoresist may include, for example, polymer materials and pigments and photosensitive materials dispersed in the polymer materials, but it is not limited thereto.

In accordance with some embodiments, the electronic device 10 may further include an opaque layer 304. The opaque layer 304 may be disposed between the light blocking layer 400 and the conductive structure 200, and at least a portion of the opaque layer 304 may overlap with the conductive structure 200. Specifically, the opaque layer 304 may at least partially overlap with the conductive structure 200 in the normal direction of the substrate 102 (e.g., the Z direction in the figure). The opaque layer 304 can block side light leakage caused by reflection of the conductive structure 200 and improve display quality. The opaque layer 304 may include a material that is substantially opaque to light.

In accordance with some embodiments, the material of the opaque layer 304 may include black photoresist, black printing ink, black resin, metal, blackened metal, oxidized metal, carbon black material, resin material, photosensitive material, another suitable material, or a combination thereof, but it is not limited thereto. The detailed structure of the opaque layer 304 will be further described below.

In addition, in accordance with some embodiments, the electronic device 10 may further include a light conversion layer 306, a light scattering layer 305, an insulating layer 301 and an adhesive layer 308. The light conversion layer 306 may be disposed on the second color filter layer 400b and the third color filter layer 400c and between two adjacent opaque layers 304. The light scattering layer 305 may be disposed on the first color filter layer 400a and between two adjacent opaque layers 304, but it is not limited thereto. The light scattering layer 305 may include a plurality of light scattering particles 3051. The insulating layer 301 may be disposed on the opaque layer 304 and the light conversion layer 306. Furthermore, the adhesive layer 308 may be disposed between the insulating layer 301 and the encapsulating layer 209 to fix the substrate 201 and the substrate 302 together.

In accordance with some embodiments, the light conversion layer 306 may include light conversion particles 3061 and light conversion particles 3062. The light conversion particles 3061 and the light conversion particles 3062 may include quantum dots, fluorescence, phosphorescence, another suitable material, or a combination thereof. In accordance with some embodiments, the material of the quantum dots may include indium phosphide (InP), indium arsenide (InAs), zinc selenide (ZnSe), cadmium selenide (CdSe), cadmium sulfide (CdS), cadmium telluride (CdTe), another suitable material or a combination thereof, but it is not limited thereto. In accordance with some embodiments, the material of the insulating layer 301 may be the same as the material of the aforementioned insulating layer 204, which will not be repeated here. Furthermore, the adhesive layer 308 may include adhesive material. In accordance with some embodiments, the material of the adhesive layer 308 may include an optical clear adhesive (OCA), an optical clear resin (OCR), a pressure sensitive adhesive (PSA), an acrylic adhesive, an acrylic resin, another suitable material, or a combination thereof, but it is not limited thereto.

Next, please refer to FIG. 4, which is an equivalent circuit diagram of the electronic device 10 in accordance with some embodiments of the present disclosure. As shown in FIG. 4, one end of the electronic unit 100a may be coupled to the signal line CL to receive the common voltage Vss, and the other end may be coupled to the thin-film transistors (labeled as T1 and T2 in the circuit diagram), and may be coupled to the storage capacitance Cst. In accordance with some embodiments, the thin-film transistor T1 may be a switching transistor, and the thin-film transistor T2 may be a driving transistor. The thin-film transistor T1 may receive the signals of the data line voltage Vdata and the scan line voltage SN to control the switch, and the thin-film transistor T2 may receive the operating voltage Vdd and the signal of the thin-film transistor T1 to control the driving of the electronic unit 100a.

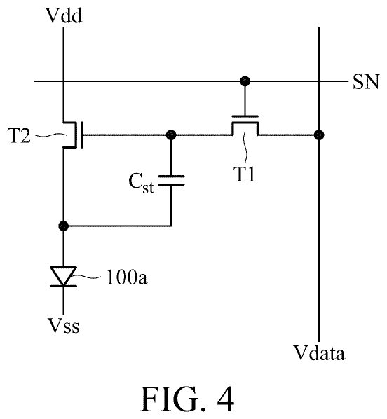

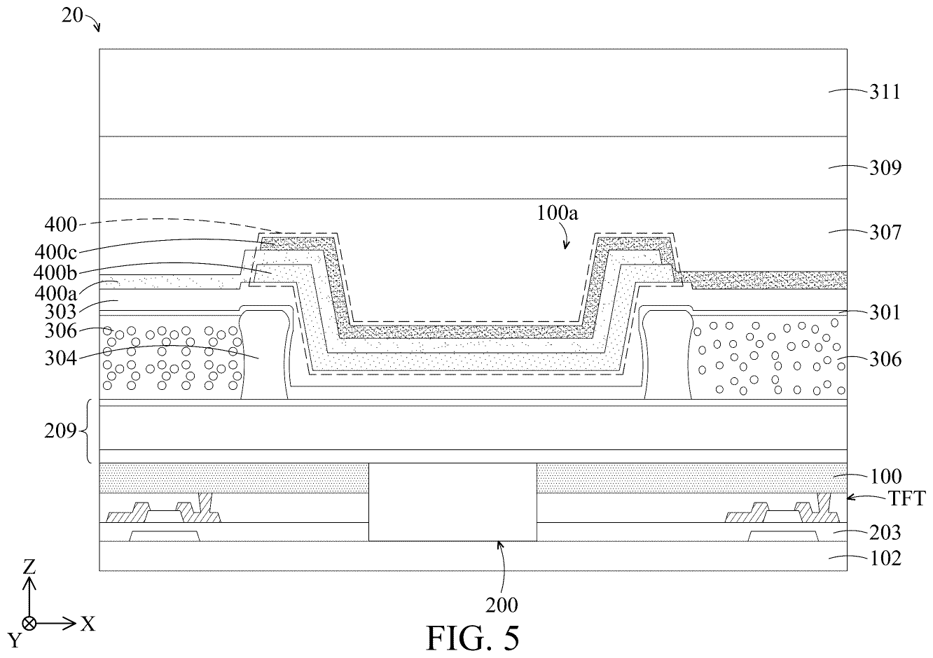

Next, please refer to FIG. 5, which is a cross-sectional diagram of an electronic device 20 in accordance with some other embodiments of the present disclosure. For clear explanation, some components of the electronic device 20 may be omitted in the drawings, and only some components are schematically shown. In accordance with some embodiments, additional features may be added to the electronic device 20 described below. Moreover, it should be understood that the same or similar components or elements in above and below contexts are represented by the same or similar reference numerals. The materials, manufacturing methods and functions of these components or elements are the same or similar to those described above, and thus will not be repeated in the following description.

FIG. 5 illustrates an embodiment of an electronic device having a single substrate. Specifically, the electronic device 20 may also include a substrate 102, a signal line CL (not illustrated) disposed on the substrate 102, a gate dielectric layer 203, a thin-film transistor TFT, an electronic unit layer 100, a conductive structure 200, a packaging layer 209 and other structures. The electronic unit layer 100 may include an electronic unit 100a, an electronic unit 100b and an electronic unit 100c. In this embodiment, the opaque layer 304 and the light conversion layer 306 are disposed on the encapsulation layer 209, and the first color filter layer 400a, the second color filter layer 400b and the third color filter layer 400c are disposed on the opaque layer 304. In addition, the first color filter layer 400a, the second color filter layer 400b and the third color filter layer 400c are disposed in the groove defined by the opaque layer 304. In other words, the light blocking layer 400 is also disposed in the groove defined by the opaque layer 304.

Furthermore, in this embodiment, the electronic device 20 may further include a low refractive index layer 303. The low refractive index layer 303 may be disposed on the insulating layer 301 and between the light blocking layer 400 and the opaque layer 304. In accordance with some embodiments, the material of the low refractive index layer 303 may include a low refractive index material. In accordance with some embodiments, the material of the low refractive index layer 303 may include an inorganic material, an organic material, a combination of high refractive index and low refractive index inorganic materials (a stack of high refractive index and low refractive index inorganic materials arranged alternately), another suitable material, or a combinations thereof, but it is not limited thereto. It should be understood that, although not illustrated in the drawings, the aforementioned electronic device 10 may also have a low refractive index layer 303.

In addition, the electronic device 20 may further include an insulating layer 307, a cover layer 309 and an optical film 311 sequentially disposed on the light blocking layer 400. The insulating layer 307 can serve as a planarization layer, the cover layer 309 can have a protective effect (e.g., waterproof and moisture-proof), and the optical film 311 can have an anti-reflective effect.

In accordance with some embodiments, the material of the insulating layer 307 may be the same as or similar to the material of the aforementioned insulating layer 205, which will not be repeated here. In accordance with some embodiments, the material of cover layer 309 may include an organic material. In accordance with some embodiments, the cover layer 309 may include an adhesive material, such as an optical clear adhesive (OCA), an optical clear resin (OCR), a pressure sensitive adhesive (PSA), an acrylic adhesive, an acrylic resin, another suitable material, or a combination thereof, but it is not limited thereto. The optical film 311 may include a multi-layer film structure in which high refractive index layers and low refractive index layers are alternately stacked.

Similarly, in this embodiment, the light blocking layer 400 may overlap with the conductive structure 200 in the normal direction of the substrate 102 (e.g., the Z direction in the figure). The light blocking layer 400 can also be used to shield the conductive structure 200, reducing the visibility of the conductive structure 200, thereby improving the display quality of the electronic device 20 and enhancing the overall performance of the electronic device. Furthermore, in the embodiments where the electronic device 20 is used as a sensing device, the conductive structure 200 can also block stray light to reduce problems such as signal interference. In addition, it should be understood that this embodiment only schematically illustrates the structure and position of the conductive structure 200. In fact, at least a portion of the opaque layer 304 may also overlap with the conductive structure 200. Specifically, the opaque layer 304 may at least partially overlap with the conductive structure 200 in the normal direction of the substrate 102 (e.g., the Z direction in the figure). The opaque layer 304 can block side light leakage caused by reflection of the conductive structure 200 and improve display quality.

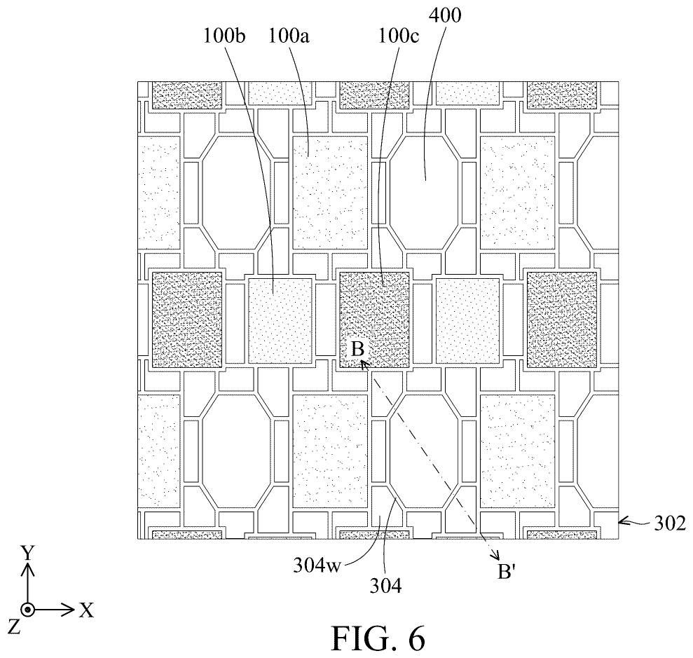

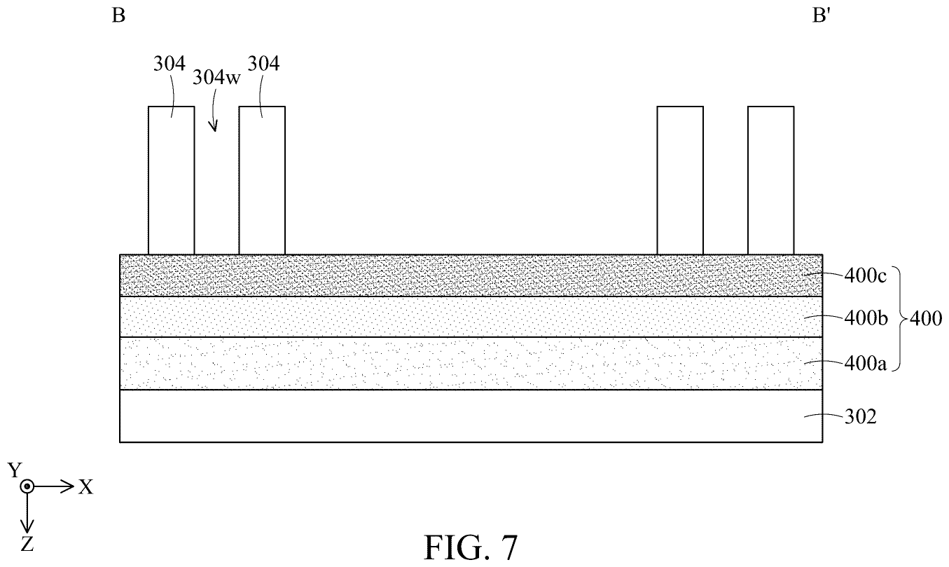

Next, please refer to FIG. 6 and FIG. 7. FIG. 6 is a top-view diagram of some components of the electronic device 10 in accordance with some embodiments of the present disclosure. FIG. 7 is a cross-sectional diagram of the electronic device 10 taken along the section line B-B′ in FIG. 6 in accordance with some embodiments of the present disclosure. Specifically, FIG. 6 and FIG. 7, illustrate the substrate 302, the opaque layer 304, the light blocking layer 400, the electronic unit 100a, the electronic unit 100b and the electronic unit 100c of the electronic device 10.

As shown in FIG. 6 and FIG. 7, in accordance with some embodiments, the opaque layer 304 has a multiple surrounding structure, and the opaque layer 304 may be disposed surrounding the electronic unit 100a, the electronic unit 100b, the electronic unit 100c and the light blocking layer 400. Moreover, the opaque layer 304 may be further surrounded into a plurality of hollow regions 304w. The hollow regions 304w may be adjacent to and disposed surrounding the electronic unit 100a, the electronic unit 100b, the electronic unit 100c and the light blocking layer 400.

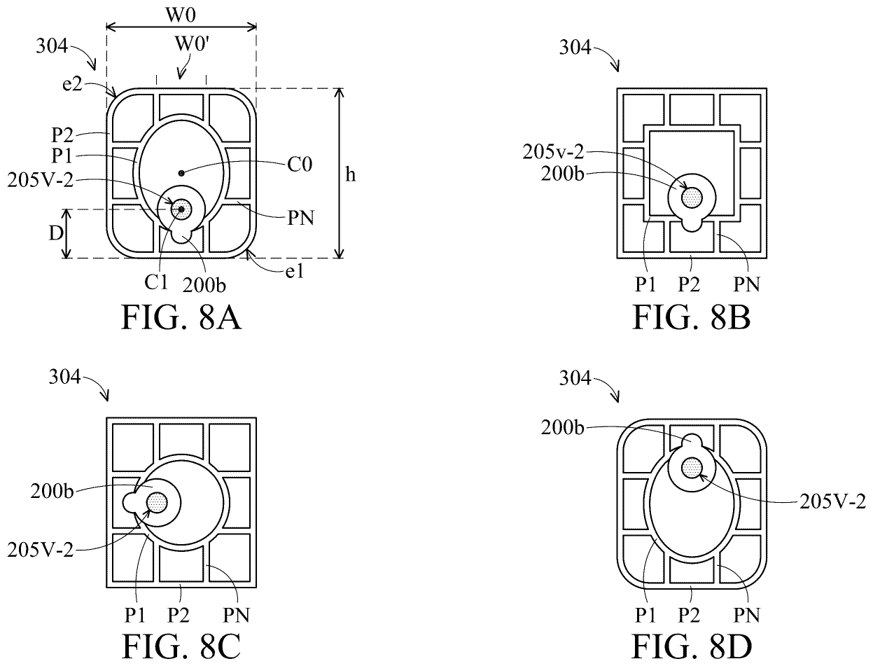

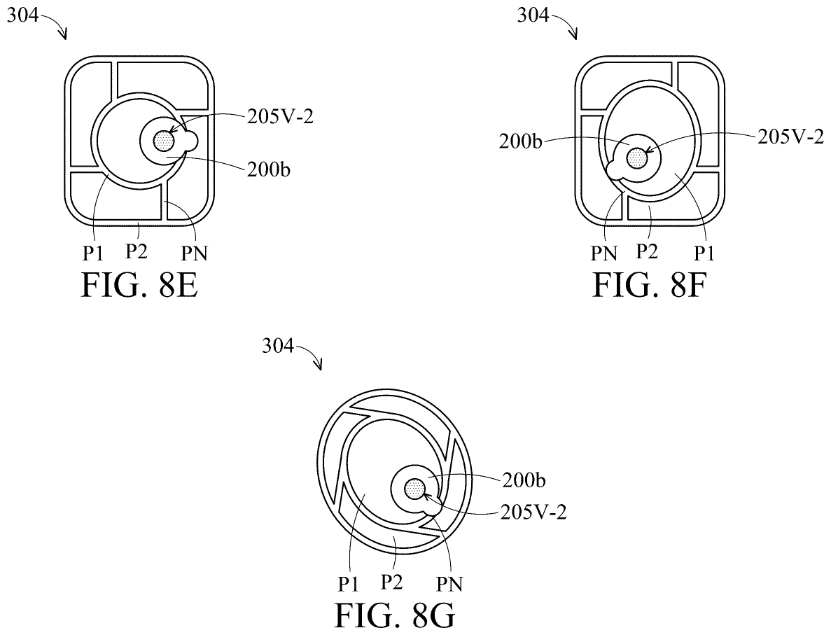

Regarding the detailed structure of the opaque layer 304, please refer to FIG. 8A to FIG. 8G. FIG. 8A to FIG. 8G, illustrate different aspects of the opaque layer 304 in accordance with some embodiments of the present disclosure.

In detail, the opaque layer 304 may include a first portion P1, a second portion P2, and a plurality of connection portions PN. The second portion P2 may surround the first portion P1, and the plurality of connection portions PN may connect the first portion P1 with the second portion P2. The first portion P1 may overlap with the conductive structure 200. Specifically, in the top view, the first portion P1 may overlap with the second conductive pattern 200b of the conductive structure 200. In accordance with some embodiments, a center C1 of the second opening 205V-2 of the second conductive pattern 200b does not overlap with a center C0 of the opaque layer 304, and the center C1 of the second opening 205V-2 may be deviated from the center C0 of the opaque layer 304. In accordance with some embodiments, the center C1 of the second opening 205V-2 of the second conductive pattern 200b may be located in the first portion P1 of the opaque layer 304.

Furthermore, in the top view of the electronic device 10, the second portion P2 has two opposite outer edges, an outer edge e1 and an outer edge e2. The distance between the two opposite outer edge e1 and outer edge e2 is h. There is a distance D between one of the two opposite outer edges close to the second opening 205V-2 (for example, the outer edge e1 in FIG. 8A) and the center C1 of the second opening 205V-2, and the distance D satisfies the following equation: 0.1 h≤D<0.5 h. That is, the distance D may be greater than or equal to 0.1 times the distance h and less than 0.5 times the distance h.

In accordance with the embodiments of the present disclosure, the center C0 refers to the geometric center of the second portion P2 of the opaque layer 304, and the center C1 refers to the geometric center of the second opening 205V-2 of the second conductive pattern 200b. The aforementioned distance h refers to the minimum distance between the two edges measured at the middle third of the width W0 of the second portion P2 (marked as W0′). The distance D refers to the minimum distance between the center C1 of the second opening 205V-2 and the outer edge e1 or the outer edge e2.

Moreover, in accordance with the embodiments of the present disclosure, an optical microscope (OM), a scanning electron microscope (SEM), a film thickness profiler (α-step), an ellipsometer or another suitable method may be used to measure the distance, pitch or angle between elements, or the width or thickness of each element. Specifically, in accordance with some embodiments, a scanning electron microscope can be used to obtain cross-sectional images of the structure and measure the distance, pitch or angle between elements, or the width or thickness of each element.

It should be noted that when the distance h and the distance D satisfy the above equation: 0.1 h≤ D<0.5 h, the second opening 205V-2 of the second conductive pattern 200b is closer to the opaque layer 304, which can enhance the effect of the opaque layer 304 in blocking the reflected light of the second conductive pattern 200b, further reduce side light leakage, and improve light extraction efficiency.

Although the center C1, distance h and distance D are not labeled in FIG. 8B to FIG. 8G, the distance h and distance D of the opaque layer 304 shown in FIG. 8B to FIG. 8G also comply with the above equation: 0.1 h≤D<0.5 h. In addition, in accordance with some embodiments, the first portion P1 of the opaque layer 304 may be circular, elliptical, quadrilateral, rectangular or another suitable shape, but it is not limited thereto. In accordance with some embodiments, the second portion P2 of the opaque layer 304 may also be circular, elliptical, quadrilateral, rectangular or another suitable shape, but it is not limited thereto. Moreover, the first portion P1 and the second portion P2 of the opaque layer 304 may have contours such as chamfers and arc corners, but they are not limited thereto.

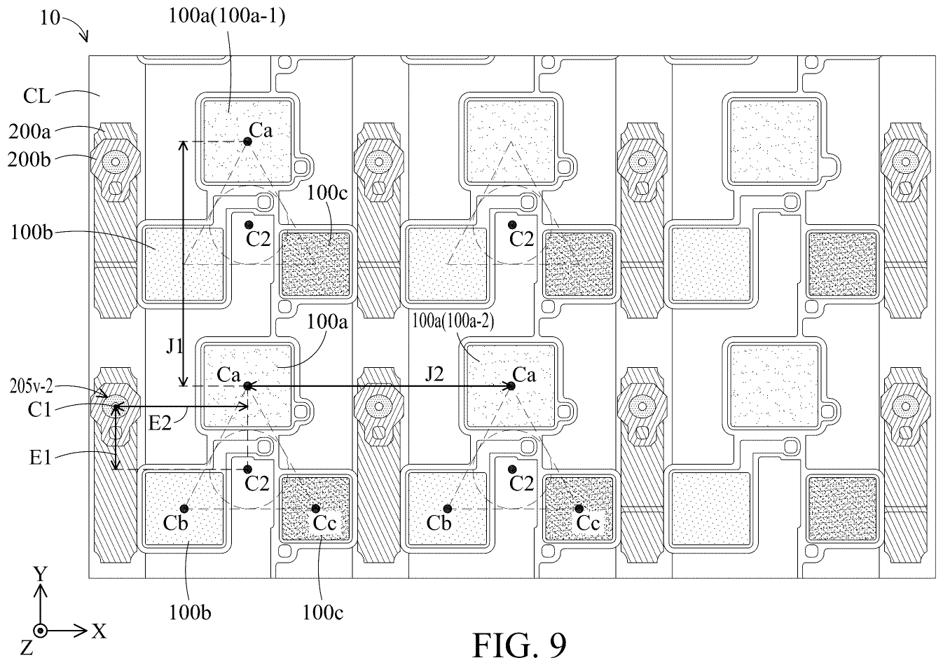

Next, please refer to FIG. 9, which is a top-view diagram of the electronic device 10 in accordance with some embodiments of the present disclosure. It should be understood that FIG. 9 only illustrates some components of the electronic device 10 to describe the arrangement relationship between the electronic unit 100a, the electronic unit 100b, the electronic unit 100c and the conductive structure 200.

As shown in FIG. 9, the electronic unit 100a, the electronic unit 100b and the electronic unit 100c are sub-units in a unit and define a unit center C2. For example, the electronic unit 100a, the electronic unit 100b and the electronic unit 100c form a unit, and the electronic unit 100a, the electronic unit 100b and the electronic unit 100c are respectively sub-units. Taking the electronic unit as a light-emitting unit as an example, the electronic unit 100a, the electronic unit 100b and the electronic unit 100c may be sub-pixels and can form a pixel. Furthermore, the electronic unit 100a and another adjacent electronic unit 100a (labeled with parentheses as 100a-1 for convenience of explanation) are arranged with a pitch J1 along the first direction (e.g., the Y direction in the figure). In the top view of the electronic device 10, there is a distance E1 between the second opening 205V-2 and the unit center C2 along the first direction, and the distance E1 satisfies the following equation: 0.05J1≤E1≤0.45J1. That is, the distance E1 may be greater than or equal to 0.05 times the pitch J1, and may be less than or equal to 0.45 times the pitch J1.

In addition, in the top view of the electronic device 10, the electronic unit 100a and another adjacent electronic unit 100a (labeled with parentheses as 100a-2 for convenience of explanation) are arranged with a pitch J2 along the second direction (e.g., the X direction in the figure). There is a distance E2 between the second opening 205V-2 and the unit center C2 along the second direction perpendicular to the first direction (e.g., the X direction in the figure), and the distance E2 satisfies the following equation: 0.2J2≤E2≤0.8J2. That is, the distance E2 may be greater than or equal to 0.2 times the pitch J2, and may be equal to or less than 0.8 times the pitch J2.

In accordance with the embodiments of the present disclosure, the pitch J1 and the pitch J2 refer to the minimum distance between the geometric centers Ca of adjacent electronic units 100a of the same type (for example, electronic units emitting the same color light), and the unit center C2 refers to the inner center of a triangle (marked by a dotted line) formed by connecting a geometric center Ca of the electronic unit 100a, a geometric center Cb of the electronic unit 100b, and a geometric center Cc of the electronic unit 100c. Furthermore, the distance E1 and the distance E2 refer to the minimum distance between the center C1 of the second opening 205V-2 of the second conductive pattern 200b and the unit center C2.

It should be noted that when the pitch J1 and the distance E1 satisfy the above equation: 0.05J1≤E1≤0.451J, or when the pitch J2 and the distance E2 satisfy the above equation: 0.2J2≤E2≤0.8J2, the interference of the reflected light of the second conductive pattern 200b to adjacent electronic units can be reduced, thereby improving the overall performance of the electronic device 10.

To summarize the above, in accordance with the embodiments of the present disclosure, the electronic device provided includes a conductive structure that electrically connects the electrodes of the electronic unit and the signal line. The conductive structure can reduce voltage drop caused by high impedance of the electrode. In addition, since the conductive structure overlaps with the light blocking layer, the obvious visibility of the conductive structure can be improved, thereby improving the problems of declining display quality or signal interference of the electronic device. The overall performance of the electronic device therefore can be enhanced.

Although some embodiments of the present disclosure and their advantages have been described in detail, it should be understood that various changes, substitutions and alterations can be made herein without departing from the spirit and scope of the disclosure as defined by the appended claims. The features of the various embodiments can be used in any combination as long as they do not depart from the spirit and scope of the present disclosure. Moreover, the scope of the present application is not intended to be limited to the particular embodiments of the process, machine, manufacture, composition of matter, means, methods and steps described in the specification. As one of ordinary skill in the art will readily appreciate from the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Thus, the appended claims are intended to include within their scope such processes, machines, manufacture, compositions of matter, means, methods or steps. Moreover, each claim constitutes an individual embodiment, and the claimed scope of the present disclosure includes the combinations of the claims and embodiments. The scope of protection of the present disclosure is subject to the definition of the scope of the appended claims. Any embodiment or claim of the present disclosure does not need to meet all the purposes, advantages, and features disclosed in the present disclosure.

What is claimed is:

1. An electronic device, comprising:
a substrate;
a signal line disposed on the substrate;
a first electronic unit disposed on the substrate and comprising a first electrode;
a conductive structure disposed on the substrate and comprising a first conductive pattern, an insulating layer disposed on the first conductive pattern, and a second conductive pattern disposed on the insulating layer, wherein the second conductive pattern is electrically connected to the first conductive pattern through a first opening of the insulating layer, and the first electrode is electrically connected to the signal line through the conductive structure; and
a light blocking layer overlapped with the conductive structure.

2. The electronic device as claimed in claim 1, wherein the first electronic unit further comprises a second electrode disposed under the first electrode and an active layer disposed between the first electrode and the second electrode, wherein the first electrode is electrically connected to the second conductive pattern through an opening of the active layer.

3. The electronic device as claimed in claim 2, wherein the insulating layer further has a second opening overlapped with the second conductive pattern, and in a top view of the electronic device, the opening of the active layer is located in the second opening.

4. The electronic device as claimed in claim 2, wherein the second conductive pattern and the second electrode are in the same layer.

5. The electronic device as claimed in claim 2, wherein the insulating layer is partially overlapped with the second electrode.

6. The electronic device as claimed in claim 3, wherein the size of the first opening is smaller than the size of the second opening.

7. The electronic device as claimed in claim 1, wherein the light blocking layer comprises a first color filter layer, a second color filter layer and a third color filter layer stacked on each other, wherein the first color filter layer, the second color filter layer and the third color filter layer have different colors.

8. The electronic device as claimed in claim 7, wherein the first color filter layer, the second color filter layer and the third color filter layer are a red color filter layer, a green color filter layer and a blue color filter layer, respectively.

9. The electronic device as claimed in claim 7, further comprising an opaque layer disposed between the light blocking layer and the conductive structure, wherein the first color filter layer, the second color filter layer and the third color filter layer are disposed in a groove defined by the opaque layer.

10. The electronic device as claimed in claim 1, further comprising an opaque layer disposed between the light blocking layer and the conductive structure, wherein at least a portion of the opaque layer is overlapped with the conductive structure.

11. The electronic device as claimed in claim 10, wherein the opaque layer comprises a first portion overlapped with the conductive structure, a second portion surrounding the first portion, and a plurality of connection portions connecting the first portion and the second portion.

12. The electronic device as claimed in claim 11, wherein the insulating layer further has a second opening overlapped with the second conductive pattern, wherein in a top view of the electronic device, the second portion has two opposite outer edges, and a distance between the two opposite outer edges is defined as h, wherein a distance D between one of the two opposite outer edges close to the second opening and a center of the second opening satisfies the following equation:
0.1 h≤D<0.5 h.

13. The electronic device as claimed in claim 11, further comprising a second electronic unit, a third electronic unit and a fourth electronic unit, wherein the first electronic unit, the second electronic unit and the third electronic unit are subunits in a unit and define a unit center, the insulating layer further has a second opening overlapped with the conductive structure, the first electronic unit and the fourth electronic unit are arranged along a first direction in a pitch J, wherein in a top view of the electronic device, a distance E1 between the second opening and the unit center along the first direction satisfies the following equation:
0.05J≤E1≤0.45J.

14. The electronic device as claimed in claim 11, further comprising a second electronic unit, a third electronic unit and a fourth electronic unit, wherein the first electronic unit, the second electronic unit and the third electronic unit are sub-units in a unit and define a unit center, the insulating layer further has a second opening overlapped with the conductive structure, wherein the first electronic unit and the fourth electronic unit are arranged along a first direction in a pitch J, wherein in a top view of the electronic device, a distance E2 between the second opening and the unit center along a second direction perpendicular to the first direction satisfies the following equation:
0.2J≤E2≤0.8J.

15. The electronic device as claimed in claim 10, wherein the insulating layer further has a second opening overlapped with the second conductive pattern, wherein a center of the second opening is deviated from a center of the opaque layer.

16. The electronic device as claimed in claim 15, wherein the center of the second opening is located in the first portion of the opaque layer.

17. The electronic device as claimed in claim 10, wherein the opaque layer has a multiple surrounding structure and a plurality of hollow regions, and the hollow regions surround the first electronic unit and the light blocking layer.

18. The electronic device as claimed in claim 1, wherein the signal line is used to receive a common voltage.

19. The electronic device as claimed in claim 1, which is a display device.

20. The electronic device as claimed in claim 1, wherein the first electronic unit is a light-emitting unit.
